(19) United States
(12) Patent Application Publication
(10) Pub. No.: US 2009/0243718 A1
(43) Pub. Date: Oct. 1, 2009

(54) High-speed modulator driver circuit with enhanced drive capability

(75) Inventor: Andrew John Bonthron, Los Angeles, CA (US)

Correspondence Address: Kitel Technologies LLC, 2130 Linda Flora Drive, Los Angeles, CA, 90077, US

(73) Assignee: Kitel Technologies LLC, Los Angeles, CA (US)

(21) Appl. No.: 12/383,911

(22) Filed: Mar. 30, 2009

Related U.S. Application Data
(60) Provisional application No. 61/072,434, filed on Mar. 31, 2008.

(51) Int. Cl. H03F 3/387

(52) U.S. Cl. 330/10

(57) ABSTRACT

Modulator driver for driving an electro-optical modulator in a high-speed optical communications system. In accordance with aspects of the present invention, a modulator driver is presented comprising an input differential limiting amplifier providing differential outputs coupled to a distributed enhanced drive output stage configuration, wherein said distributed enhanced drive output stage configuration comprises a plurality of inductively coupled enhanced drive differential amplifiers, each of said enhanced drive differential amplifiers comprising a plurality of transistors in a cascode configuration whereby the control electrode of the upper transistor in said cascode configuration is biased by a voltage having a modulation component derived from either an input signal to or output signal from said enhanced drive differential amplifier, for the purpose of providing an enhanced output voltage swing capability that exceeds the breakdown voltage of a single transistor. Other methods and apparatus are presented.

### CROSS-REFERENCE TO RELATED APPLICATIONS

This application claims the benefit of U.S. Provisional Application No. 61/072,434, filed Mar. 31, 2008 by the present inventor, which is incorporated herein by reference.

### FIELD OF THE INVENTION

The subject matter disclosed generally relates to the field of digital communications devices. More specifically, the subject matter disclosed relates to electronic arrangements for high-speed, electro-optical data transmission applications.

### BACKGROUND OF THE INVENTION

An important element in high-speed fiber-optic transmission systems is the ability to optically encode data bits for transport in optical fiber media. One way this is achieved is through the modulation of the output of a continuous-wave laser source by an electro-optical modulator, whose output is coupled to an optical fiber for transmission. Many applications require high quality optical modulation performance, which imposes amplitude and signal quality requirements on the drive electronics, often referred to as a modulator driver, required to interface with the electro-optical modulator. Additionally, as optical network data rates increase, many applications require the electrical modulator driver to maintain the appropriate signal requirements for achieving high quality optical modulation performance at higher data rates.

FIG. 1 illustrates the top view of typical electro-optical modulator integrated circuit known in the art which is capable of providing modulation of an optical signal, based on a Mach-Zehnder interferometer technique with single-ended electrical drive input. A continuous-wave optical signal is input to an optical waveguide 12 where it is split into two paths. An electrical data signal from a single-ended modulator driver is input to the RF IN port where it travels along an electrical transmission line 14 between the optical waveguide paths, and creates an electric field between the transmission line and two ground electrodes 21, 22. Due to the geometry of the layout, the electric field distribution will have opposite polarity in each of the optical waveguides, producing a change in the phase in each of the optical waveguides that has opposite direction. With a sufficiently large electrical signal amplitude, typically 4 to 8 volts peak-to-peak, the phase shifts induced in the optical waveguide paths, when combined, will cause the optical output signal to be modulated.

A large amplitude drive signal is difficult to achieve at high-speed data rates due a number of factors. One factor is that in many cases, transistor device geometries are reduced in order to increase the speed of operation. This is commonly referred to as device scaling, and typically results in lower breakdown voltages for the transistor devices. While this may not pose a problem for small digital logic swings, it can impose a limitation in the maximum output drive signal amplitude achievable, which can be detrimental for modulator driver applications. Another factor is that the parasitics of the transistor device sizes required to generate the large electrical output voltage swings can limit the signal transition speeds, and thus the data rate.

One method known in the art for overcoming the data rate limitations imposed by the device parasitics is the use of a single-ended distributed amplifier. A typical single-ended distributed amplifier topology is illustrated in FIG. 2. In this topology, an input signal travels along an artificial transmission line formed by inductive elements 31 and the input capacitance of transistor amplifier stages 40. The traveling wave input signal is amplified by the transistor amplifier stages 40 which in turn output signals onto an output artificial transmission line formed by inductive elements 32 and the output capacitance of the transistor amplifier stages 40. The output signals will have a forward and reverse traveling wave component, where the reverse traveling wave component is terminated by the termination 35, and the forward traveling wave signal will be output from the distributed amplifier. A bias-T structure 42 is typically disposed at the output port and used to provide access to a positive supply voltage VCC for biasing of the transistor amplifier stages 40.

While the topology in FIG. 2 can provide wideband amplification and large output amplitude capability, it has several limitations when used for modulator driver applications. One limitation is that it does not overcome the output signal amplitude limitations imposed by transistor breakdown voltages. Another limitation is that stabilization of the output signal amplitude over a range of input signal amplitudes can be difficult, typically requiring amplifier saturation which can cause poorly controlled output signal rise and fall times. A further limitation is that adjustment of the output signal amplitude can be difficult, typically requiring external circuitry for simultaneous adjustment of the supply voltage VCC and gate bias voltage VG.

Another circuit known in the art that can be utilized for modulator driver applications is shown in FIG. 3. In this circuit arrangement, an input signal is coupled to a cascode differential amplifier topology utilizing transistors QA, QB, QC, QD and the complimentary output signals are generated across load resistors RA, RB. While this circuit topology has some advantages as compared to the aforementioned distributed amplifier, its speed of operation is limited by the transistor parasitics. In addition, since the base bias of the upper transistors QC, QD in the cascode configuration is fixed to a DC bias potential, the output signal swing is limited by the breakdown voltage rating of the transistors QC, QD in this configuration.

Accordingly, it would be desirable to have a modulator driver architecture capable of large output amplitude and high-speed data transmission while being compatible with low breakdown voltage transistor processes. Also, it would be desirable to have a modulator driver architecture with input limiting function capable of providing a stabilized output signal amplitude over a range of input signal amplitudes. In addition, it would be desirable to have a modulator driver architecture with a simple method for adjustment of the output drive signal amplitude. Furthermore, it would be desirable to have a modulator driver architecture compatible with compact, monolithic process fabrication techniques with a minimum of external components required for operation.

### SUMMARY OF THE INVENTION

Modulator driver for driving an electro-optical modulator in a high-speed optical communications system. In accordance with aspects of the present invention, a modulator driver is presented comprising an input differential limiting amplifier providing differential outputs coupled to a distributed enhanced drive output stage configuration, wherein said distributed enhanced drive output stage configuration comprises a plurality of inductively coupled enhanced drive differential amplifiers, each of said enhanced drive differential amplifiers comprising a plurality of transistors in a cascode configuration whereby the control electrode of the upper transistor in said cascode configuration is biased by a voltage having a modulation component derived from either an input signal to or output signal from said enhanced drive differential amplifier, for the purpose of providing an enhanced output voltage swing capability that exceeds the breakdown voltage of a single transistor. Other methods and apparatus are presented.

### BRIEF DESCRIPTION OF THE DRAWINGS

The accompanying drawings are for the purpose of illustrating and expounding the features involved in the present invention for a more complete understanding, and not meant to be considered as a limitation, wherein:

FIG. 1 is a diagram of a known electro-optical modulator architecture with a single-ended electrical drive port structure.

FIG. 2 is a schematic diagram of a known single-ended distributed amplifier architecture utilized for modulator driver applications.

FIG. 3 is a schematic diagram of a known differential cascode amplifier circuit structure.

FIG. 4 is a schematic diagram illustrating one modulator driver arrangement for use with an electro-optical modulator according to aspects of the present invention.

FIG. 5 is a schematic diagram illustrating one embodiment of a distributed enhanced drive output stage according to aspects of the present invention.

FIG. 6 is a schematic diagram illustrating one embodiment of an enhanced drive differential amplifier according to aspects of the present invention.

FIG. 7 is a schematic diagram illustrating another embodiment of an enhanced drive differential amplifier according to aspects of the present invention.

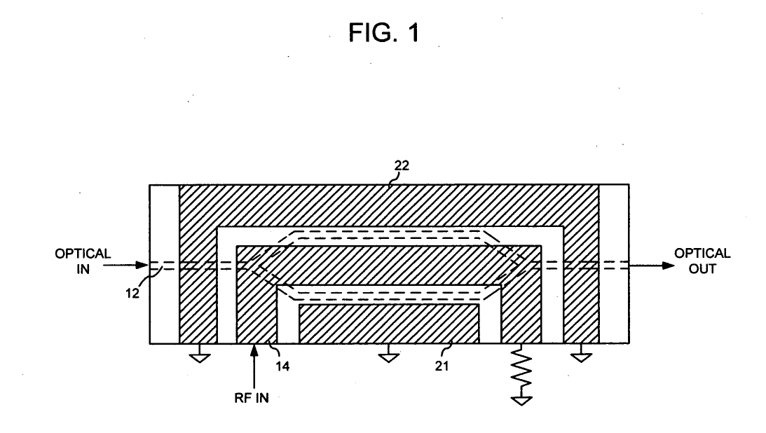

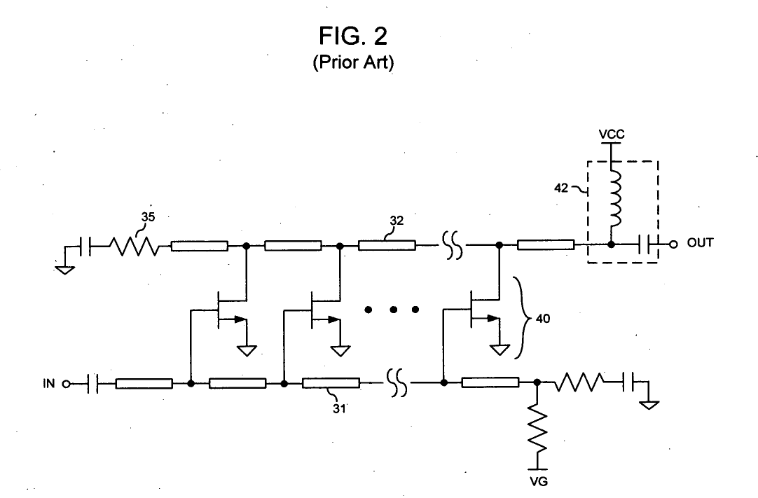

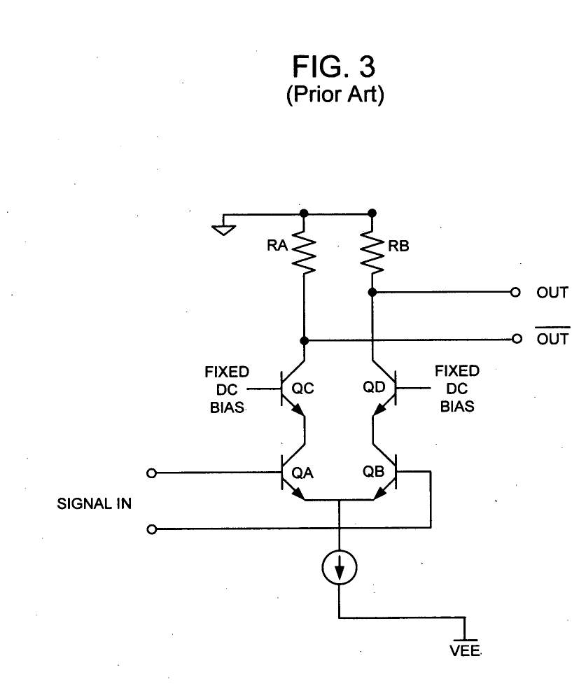

### DETAILED DESCRIPTION OF THE INVENTION

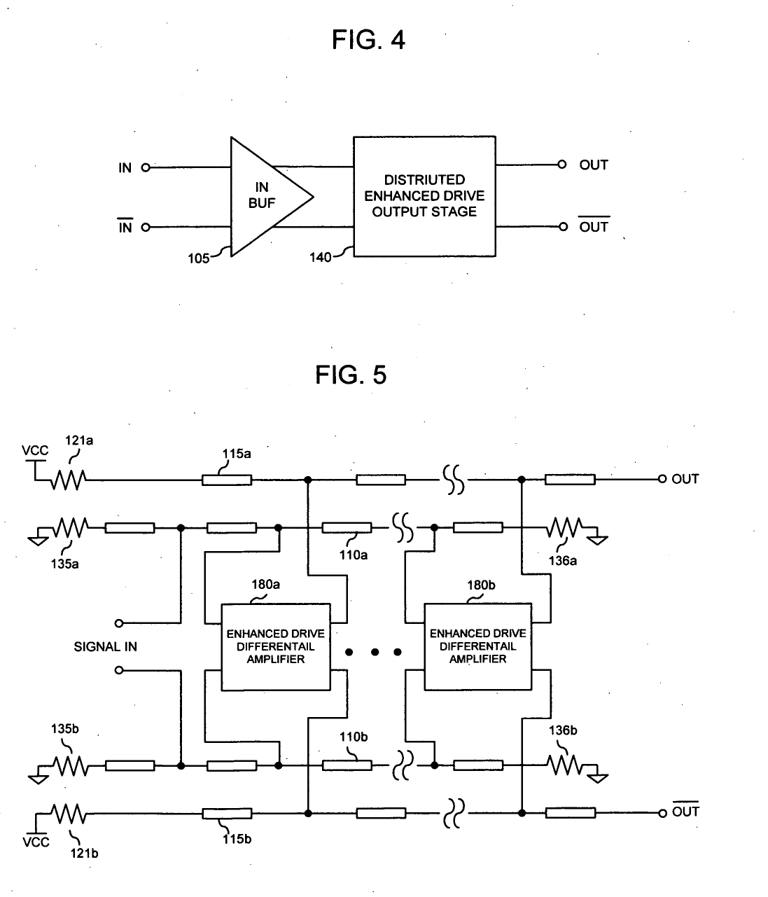

A modulator driver arrangement is presented in FIG. 4 as one embodiment of aspects of the present invention. In this arrangement, an input signal is coupled to an input buffer 105, which provides an output differential signal. The input buffer 105 has the ability to accept differential input signals as illustrated in FIG. 4, or a single-ended input signal coupled to one input of the input buffer 105 through a DC blocking capacitor, with the input buffer 105 further providing a single-ended to differential signal conversion function. Additionally, the input buffer 105 further provides an input signal limiting function, providing a differential output signal with a leveled amplitude for input signals of varying amplitudes. The output differential signal from input buffer 105 is coupled to a distributed enhanced drive output stage 140, which provides the output drive signals for the modulator driver arrangement. The distributed enhanced drive output stage 140 is comprised of a plurality of inductively coupled differential amplifiers, each providing an enhanced drive capability enabling output signal amplitudes having a peak-to-peak voltage swing capability that exceeds the breakdown voltage of the transistors utilized in the differential amplifier circuitry. In this way, the modulator driver arrangement simultaneously mitigates the bandwidth limitations of the device parasitics as well as the output swing limitations due to transistor breakdown voltages, through the use of this differential distributed amplifier topology with enhanced drive capability, allowing high-speed operation and compatibility with low breakdown fabrication processes. Furthermore, the limiting amplifier functionality of the input buffer allows generation of consistent output signals over a range of input signal amplitudes.

A distributed circuit arrangement is illustrated in FIG. 5 as one embodiment of distributed enhanced drive output stage 140 according to aspects of the present invention. In this arrangement, an input signal is coupled to a differential artificial transmission line structure formed by inductive elements 110a, 110b and the input capacitance of signal inputs to enhanced drive differential amplifiers 180a, 180b, and further comprising reverse differential traveling wave signal termination resistors 135a, 135b as well as forward differential traveling wave signal termination resistors 136a, 136b. The enhanced drive differential amplifiers 180a, 180b provide differential output signals coupled to an output differential artificial transmission line structure formed by inductive elements 115a, 115b and the output capacitance of signal outputs from enhanced drive differential amplifiers 180a, 180b, and further comprising reverse traveling wave signal termination resistors 121a, 121b as well as output ports (OUT) for transmission of the forward traveling wave output signals. Termination resistors 121a, 121b are coupled to a biasing voltage VCC in order to provide sufficient headroom for generation of large output signal amplitudes. This distributed enhanced drive output stage arrangement provides the capability of generating high-speed output signals having amplitudes that exceed the breakdown voltage of the transistors utilized in the differential amplifier circuitry. Furthermore, this arrangement is compatible with compact, monolithic fabrication of the modulator driver requiring only a minimum of external components for proper operation.

The modulator driver arrangements illustrated in FIGS. 4 and 5 can be modified according to aspects of the present invention. One example of such a modification, not meant as a limitation, is the use of multiple lumped-element stages for the realization of the input buffer 105 or enhanced drive differential amplifiers 180a, 180b. Another example of such a modification, not meant as a limitation, is to vary the number of enhanced drive differential amplifiers 180a, 180b that are utilized to comprise the distributed output stage of the modulator driver, trading-off application requirements for output signal amplitude, operating frequency, size and cost. A variety of elements known to those skilled in the art, such as amplifiers, buffers, gain blocks, limiters, equalizers, resistors, capacitors, inductors, bias-T components, transmission lines, and the like, can be added to or deleted from the described arrangement, or the position of existing elements may be modified, without changing the basic form or spirit of the invention.

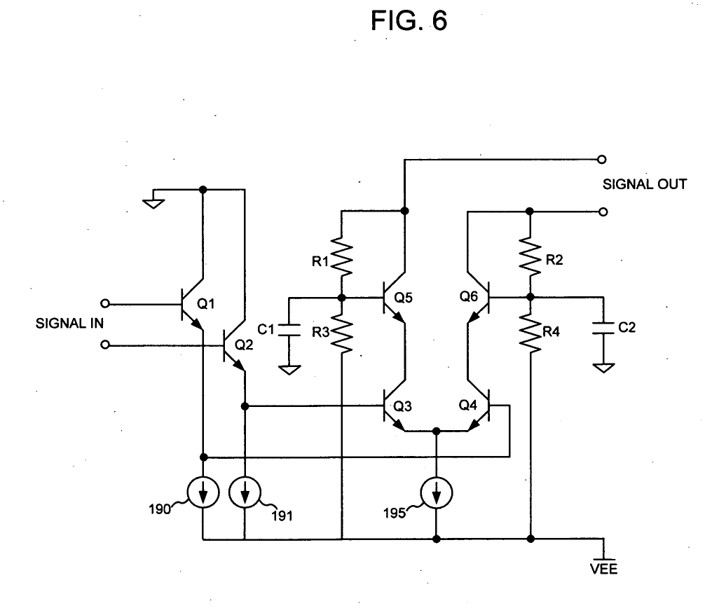

A circuit arrangement is illustrated in FIG. 6 as one embodiment of an enhanced drive differential amplifier 180a, 180b according to aspects of the present invention. In this arrangement, a differential input signal (SIGNAL IN) is coupled to transistors Q1, Q2 which form an emitter-follower configuration with current sources 190, 191. The emitter-follower transistors Q1, Q2 provide a high input impedance and low signal loss, which is compatible with the distributed input signal structure presented to the enhanced drive differential amplifiers 180a, 180b. The output signals from the emitter-follower configuration are coupled to transistors Q3, Q4 which form a differential cascode configuration with transistors Q5, Q6 and current source 195. The differential output signals (SIGNAL OUT) are provided by the collectors of transistors Q5, Q6. However, this arrangement differs from a standard cascode amplifier in a very significant way. In a standard cascode amplifier, the bases of transistors Q5, Q6 would be biased by a fixed, DC potential, such that the output signal voltage swing present at the collector terminals of transistors Q5, Q6 would create a time-varying collector-base and collector-emitter voltage potential across transistors Q5, Q6 that can exceed the rated breakdown voltage of the transistor. In the arrangement illustrated in FIG. 6, resistors R1, R2, R3, R4 are added to create a voltage feedback mechanism that varies the base bias potential of transistors Q5, Q6 in relation to the modulated output voltage present at the collectors of transistors Q5, Q6. In this way, the collector-base and collector-emitter voltage potential across transistors Q5, Q6 is significantly reduced such that the output voltage swing capability exceeds the breakdown voltage rating of the individual transistor devices. The values of the resistors R1-R4 determine the amount of voltage feedback, and thus the modulation component of the bias presented to the bases of transistors Q5, Q6, which controls the amount of voltage swing that is shared across the upper transistors Q5, Q6 and lower transistors Q3, Q4 in the cascode arrangement. Capacitors C1 and C2 are utilized to optimize signal timing in this circuit arrangement. Current source 195 provides the output current which is steered between the differential signal output lines, and the amplitude of the output differential signal is proportional to the current of the current source 195, which provides a simple method of output amplitude adjustment through adjustment of the current. Additionally, this configuration allows monolithic fabrication of the circuitry of a modulator driver having an architecture as illustrated in FIGS. 4 and 5, requiring only a minimum of external components for proper operation.

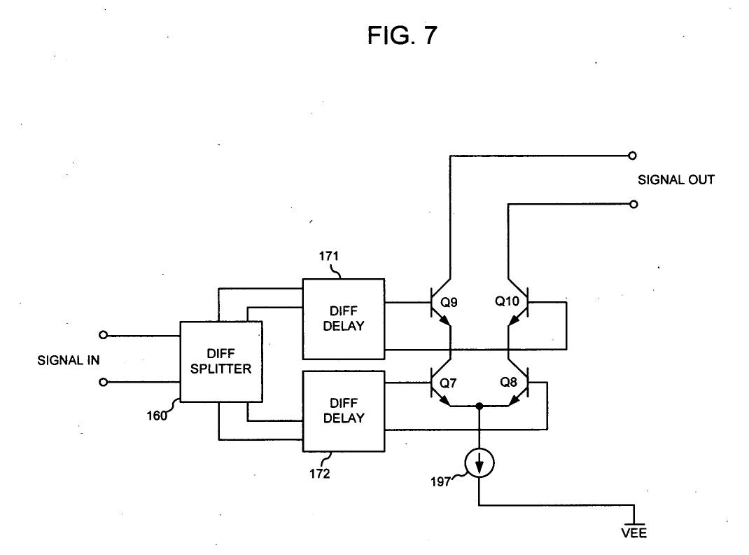

A circuit arrangement is illustrated in FIG. 7 as another embodiment of an enhanced drive differential amplifier 180a, 180b according to aspects of the present invention. In this arrangement, a differential input signal (SIGNAL IN) is coupled to a differential signal splitter 160 which outputs a first and a second differential output signal. The first differential output signal is coupled to the input of a first differential delay 172, which provides a delayed differential output signal to transistors Q7, Q8 which form the lower transistors in a differential cascode configuration. The second differential output signal from differential signal splitter 160 is coupled to the input of a second differential delay 171, which provides a delayed differential output signal to transistors Q9, Q10 which form the upper transistors in said differential cascode configuration. This circuit arrangement provides a voltage modulation mechanism that varies the base bias potential of transistors Q9, Q10 in relation to the modulated output voltage present at the collectors of transistors Q9, Q10. In this way, the collector-base and collector-emitter voltage potential across transistors Q9, Q10 is significantly reduced such that the output voltage swing capability exceeds the breakdown voltage rating of the individual transistor devices. The magnitude of the signals provided by the differential delay 171 provides the magnitude of the modulation component of the bias presented to the bases of transistors Q9, Q10, which controls the amount of output voltage swing that is shared across the upper transistors Q9, Q10 and lower transistors Q7, Q8 in the cascode arrangement. The amount of delay in differential delays 171, 172 need not be the same, and preferably are different, in order to optimize the signal timing in this circuit arrangement. Current source 197 provides the output current which is steered between the differential signal output lines, and the amplitude of the output differential signal is proportional to the current of the current source 197, which provides a simple method of output amplitude adjustment through adjustment of the current. Additionally, this configuration allows monolithic fabrication of the circuitry of a modulator driver having an architecture as illustrated in FIGS. 4 and 5, requiring only a minimum of external components for proper operation.

The circuit arrangements illustrated in FIGS. 6 and 7 can be modified according to aspects of the present invention. One example of such a modification, not meant as a limitation, is the use of multiple stages of circuitry for realization of the enhanced drive differential amplifier functionality. Another example of such a modification, not meant as a limitation, is the use of other differential circuit topologies to provide gain within differential amplifier functional blocks, such as differential Darlington amplifier circuitry, Cherry-Hooper amplifier circuitry, or any combination of these and the previously described circuits. A further example of such a modification, not meant as a limitation, is the use of CMOS, bi-CMOS, FET, HEMT, HBT, or DHBT transistors to realize the circuit functions rather than the illustrated bi-polar transistors. A yet further example of such a modification, not meant as a limitation, is the use of additional series-connected transistors and associated circuitry in the output stage stacked arrangement, further enhancing the output drive capability. A variety of elements known to those skilled in the art, such as amplifiers, buffers, gain blocks, equalizers, resistors, capacitors, inductors, transistors, transmission lines, and the like, can be added to or deleted from the described arrangement, or the position of existing elements may be modified, without changing the basic form or spirit of the invention.

Although the preceding examples have illustrated single-channel modulator driver arrangements, the concepts and methods described are extendable to multi-channel driver arrays without departing from the spirit of the present invention. In addition, although the preceding examples illustrate the use of a negative supply voltage, a positive supply voltage, and ground as biasing potentials, the concepts and methods described are extendable to other multi-potential biasing arrangements without departing from the present invention.

The preceding concepts, methods, and architectural elements described are meant to illustrate advantages and aspects of the present invention, not as a limitation. Different combinations of these concepts, methods, and architectural elements than that described in the preceding figures can be utilized by one of ordinary skill in the art without departing from the spirit of the present invention.

While certain exemplary embodiments have been described and shown in the accompanying drawings, it is to be understood that such embodiments are merely illustrative of and not restrictive on the broad invention, and that this invention not be limited to the specific constructions and arrangements shown and described, since various other modifications may occur to those ordinarily skilled in the art.

What is claimed is:

1. A modulator driver apparatus comprising:
a distributed amplifier formed by a plurality of inductively coupled amplifier stages, said distributed amplifier configured to generate an output signal in response to an input signal;
a plurality of transistors arranged in a cascode configuration within at least one of said amplifier stages;
an upper transistor within said cascode configuration having a control electrode configured to accept a time-varying bias voltage; and
a biasing circuit which provides said time-varying bias voltage to said control electrode, wherein a portion of said time-varying bias voltage is derived from at least one of a signal input to, or output from, said amplifier stages.

2. The apparatus of claim 1, whereby said time-varying bias voltage effects a reduction in the maximum voltage potential presented across the terminals of said upper transistor during the generation of said output signal.

3. The apparatus of claim 1, wherein said upper transistor is arranged in a common-base configuration.

4. The apparatus of claim 1, wherein said upper transistor is arranged in a common-gate configuration.

5. The apparatus of claim 1, wherein said control electrode is the base of a transistor.

6. The apparatus of claim 1, wherein said control electrode is the gate of a transistor.

7. The apparatus of claim 1, further comprising a limiting pre-amplifier circuit having outputs coupled to the inputs of said distributed amplifier.

8. The apparatus of claim 1, wherein each of said amplifier stages has a differential input and a differential output signal configuration.

9. The apparatus of claim 1, wherein each of said amplifier stages has a single-ended input and a single-ended output signal configuration.

10. The apparatus of claim 1, wherein each of said amplifier stages has a differential input and a single-ended output signal configuration.

11. The apparatus of claim 10, wherein each of said amplifier stages contain circuitry that generates differential signals in response to differential input signals, terminates one of said differential signals, and provides the other of said differential signals as a single-ended output signal.

12. The apparatus of claim 1, wherein said amplifier stages are enhanced drive differential amplifiers.

13. The apparatus of claim 1, wherein said distributed amplifier is a distributed enhanced drive output stage.

14. The apparatus of claim 1, wherein metal interconnect inductance provides said inductive coupling mechanism.

15. The apparatus of claim 1, further comprising one or more additional transistors connected in series with the signal path of said cascode configuration.

16. The apparatus of claim 15, further comprising one or more additional time-varying bias voltages provided to the control electrodes of the additional transistors connected in series with the signal path.

17. The apparatus of claim 1, wherein the output signal of said distributed amplifier is coupled to an electro-optical modulator in an optical communications system

18. A modulator driver method comprising:
generating an output signal in response to an input signal, wherein said output signal is generated using a distributed amplifier configuration comprising a plurality of inductively coupled amplifier stages;
providing a time-varying bias voltage to said inductively coupled amplifier stages; and
biasing a transistor within said inductively coupled amplifier stages with said time-varying bias voltage to effect a reduction in the maximum voltage potential presented across the terminals of said transistor during the generation of said output signal.

19. The method of claim 18, wherein said inductively coupled amplifier stages comprise transistors arranged in a cascode configuration.

20. The method of claim 18, wherein a portion of said time-varying bias voltage is derived from at least one of a signal input to, or output from, said inductively coupled amplifier stages.

21. The method of claim 18, further comprising a plurality of time-varying bias voltages provided to said inductively coupled amplifier stages.

22. The method of claim 18, wherein said output signal is provided to an electro-optical modulator for the purpose of modulating at least one of the amplitude or phase of light in an optical communications system.
